(19) United States
(12) Patent Application Publication
(10) Pub. No.: US 2026/0089891 A1
(43) Pub. Date: Mar. 26, 2026

(54) HEATER FOR EXPANSION CARD BRACKET

(71) Applicant: Quanta Computer Inc., Taoyuan City (TW)

(72) Inventors: Yi-Chieh CHEN, Taoyuan City (TW); Yueh-Chang WU, Taoyuan City (TW); Te-Chuan WANG, Taoyuan City (TW); Wei-Ju CHEN, Taoyuan City (TW); Chia-Ching CHU, Taoyuan City (TW)

(21) Appl. No.: 18/897,495

(22) Filed: Sep. 26, 2024

(51) Int. Cl. H05K 7/20; F16B 5/02

(52) U.S. Cl. CPC H05K 7/20709; F16B 5/02

(57) ABSTRACT

An expansion card bracket for allowing operation of an expansion card in extreme cold conditions is disclosed. The expansion card bracket includes a base plate having a top surface to hold the expansion card. An aperture is formed through the base plate. A heater module with a thin film heater is attached to the base plate. The heater module is aligned with the aperture to heat an area of the expansion card. A thermal pad is inserted between the thin film heater and the expansion card. The expansion card bracket allows the heater module to be attached after the installation of the expansion card to allow for better thermal transmission and to prevent inadvertent damage or misalignment of the thermal pad.

### TECHNICAL FIELD

The present invention relates generally to a heater for an expansion card, and more specifically, to an expansion card bracket structure having a separately installable heater to allow for more efficient operation of an expansion card in extreme cold conditions.

### BACKGROUND

With advancements in the telecommunications industry, the demand for network computing is increasing. Applications such as industrial automation, retail analytics, telemedicine, and smart homes all require sufficient computing bandwidth in telecommunication networks. Telecommunication devices, such as base stations for cellular networks, typically have compartments for holding various components. The compartments protect the components from adverse environmental conditions and unauthorized access.

5G components such as radio units (RU), distributed units (DU), active antenna units (AAU), or edge servers require high performance in all environments. Such components are designed to allow the installation of additional expansion cards that enhance performance. The expansion cards may hold components such as memory, processors, network interface elements or the like to increase functionality of the component. Such expansion cards are manufactured according to well-known standards such as the Peripheral Component Interconnect express (PCIe) standard.

To provide customers with a stable and low-latency network environment and to utilize resources more efficiently, edge servers are widely deployed in various environments to support a 5G network. The Network Equipment Building System (NEBS) GR-3108 standard specifies that equipment shall be able to be started or restarted during extreme cold winter weather and a system shall not sustain any damage or deterioration of functional performance as a result of this exposure or cold temperature start (e.g., a cold temperature start during −40° C.). An edge server designed for compliance with the GR-3108 will have an exterior chassis that holds a motherboard and a bracket structure for a PCIe compatible expansion card.

Generally, the minimum operating temperature of a PCIe expansion card is 0° C., which does not comply with the cold start requirement of operating during −40° C. In order to maintain operation of expansion cards installed in servers in cold conditions and to comply with the GR-3108 standard, current bracket structures for holding such expansion cards may include a heater. FIG. 1A is a side view of a known expansion card bracket 10 that is attached to a motherboard 12 of an edge server. FIG. 1B is a top perspective view of an expansion card 14 installed in the known expansion card bracket 10. The expansion card bracket 10 supports the expansion card 14. In this example, the expansion card 14 is a PCIe type expansion card. The expansion card bracket 10 includes a base plate 16 that is attached to supports 18 extending from the motherboard 12.

The expansion card 14 includes a circuit board 20 that includes electronic components such as a processor. A heat sink 22 is attached over the processor. The base plate 16 supports a riser 32. One edge of the riser 32 includes an edge connector that is inserted in an expansion socket 34 on the motherboard 12. One surface of the riser 32 holds a perpendicular connector socket 36 that allows electrical connection to a golden finger type edge connector on the circuit board 20 of the expansion card 14. A support 38 extending from the base plate 16 has a slot 40 that allows an opposite edge of the circuit board 20 to be inserted and thus holds the circuit board 20 above the base plate 16.

In order to keep the expansion card 14 at a sufficient temperature to operate in cold conditions, a film heater 50 is located on the area of the base plate 16 directly under the area of the expansion card 14 that includes the processor. The film heater 50 has a series of conductive traces that are powered via a power supply to emit heat. A thermal pad 52 sits between the film heater 50 and the base plate 16 of the expansion card bracket 10. The film heater 50 transmits heat through the thermal pad 52 to the processor of the expansion card 14 to keep the processor at a sufficiently high temperature to operate. The thermal pad 52 must be aligned with the area of the film heater 50 to maximize heat transmission to the expansion card 14.

During assembly the PCIe expansion card 14 is inserted in place by connecting an edge of the circuit board 20 with golden finger connectors to the connector socket 36 on the riser 32. After the edge of the circuit board 20 is inserted in the connector socket 36, the other edge of the circuit board 20 may be inserted in the slot 40 of the support 38. This secures the circuit board 20 over the thermal pad 52. However, the motion of sliding the circuit board 20 into the connector socket 36 may be impeded by the thermal pad 52, thereby making assembly difficult as shown in FIG. 1A. Additionally, the process of inserting the expansion card 14 can damage the surface of the thermal pad 52, thus reducing heat transfer efficiency from the film heater 50 to the expansion card 14. Finally, the insertion of the expansion card 14 can also cause the thermal pad 52 to shift during installation and thus move out of alignment with the film heater 50. This potentially leads to ineffective heat dissipation from the film heater 50 and poses a risk of the film heater 50 burning out.

FIG. 1C shows a perspective exploded view of the expansion card bracket 10 with the expansion card 14, where the thermal pad 52 has been shifted out of alignment with the film heater 50. The circuit board 20 has been lifted up to show the position of an edge connector 54 relative to the connector socket 36 of the riser 32. The bottom of the circuit board 20 includes an area 56 that is under the processor and thus must be inserted in alignment on the thermal pad 52 to allow efficient heating of the processor. The thermal pad 52 in turn must be aligned over the area of the film heater 50. In this example, the installation of the expansion card 14 has moved the thermal pad 52 out of alignment with the film heater 50. The misaligned position of the thermal pad 52 thus exposes certain heating elements 60 of the film heater 50, as well as preventing certain areas of the bottom surface under the processor on the circuit board 20 from receiving heat through the thermal pad 52. This reduces heat dissipation from the film heater 50 to the expansion card 14 and potentially causes a burnout of the heating elements 60 of the film heater 50 from the power accumulation on the exposed area of heating elements 60 due to ineffective heat transfer to the expansion card 14.

Thus, present installation methods for heating expansion cards mounted on bracket structures require a thermal pad for transmitting heat from a film heater fixed to the bracket and suffer from a number of drawbacks. There is interference between the expansion card 14 and the thermal pad 52 that makes installation difficult. Displacement of the thermal pad 52 can lead to the heater burning out and thus preventing operating the expansion card in cold conditions. The thermal pad 52 may be broken during installation and thus may lead to lower heater efficiency because of lower heat transmission through the thermal pad 52. Finally, the thermal pad 52 must be compressed to ensure proper contact between the film heater 50 and the expansion card 14. Therefore, the thermal pad 52 is designed to be thicker than the gap between the expansion card 14 and the expansion card bracket 10. However, compressing the thermal pad 52 creates a force in the opposite direction on the expansion card 14. This force can push against the expansion card 14 causing it to bend and may lead to contact issues between the expansion card 14 and the connector 36 on the riser.

Thus, there is a need for a structure of a bracket for an expansion card to allow fixed alignment of a heating pad with a film heater and an area for a component on the expansion card. There is another need for a bracket structure that improves heater efficiency and saves power consumption during cold start of a component with an expansion card.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, an expansion card bracket is disclosed. The expansion card bracket includes a base plate having a top surface to hold an expansion card. An aperture is formed through the base plate. A heater module is attached to the base plate and aligned with the aperture to heat an area of the expansion card.

A further implementation of the example expansion card bracket is where the expansion card is compliant with PCIe standards. Another implementation is where the example expansion card bracket includes a riser board on one end of the base plate and a card support on the other end of the base plate. The riser board includes a first connector mateable with the expansion card and a second connector mateable to a socket on a main circuit board. Another implementation is where the heater module includes a film heater. Another implementation is where the heater module includes a heat transmission pad positioned on the film heater. The heat transmission pad allows heat transmission between the film heater and the expansion card. Another implementation is where the heater module includes a tab with an attachment mechanism for attachment to a bottom surface of the base plate. Another implementation is where the attachment mechanism is a screw. Another implementation is where the example expansion card bracket includes a side wall perpendicular to the base plate.

Another disclosed aspect is a heater module for mating to an expansion card bracket. The heater module includes a spreader plate having an attachment mechanism for attachment to a base plate of the expansion card bracket. The spreader plate is positioned over an aperture of the base plate. A thin film heater is positioned on the spreader plate to be aligned with the aperture of the base plate of the expansion card bracket. A heat transmission pad is positioned on the film heater.

A further implementation of the example heater module is where the expansion card bracket holds an expansion card compliant with PCIe standards. Another implementation is where the spreader plate includes a tab with the attachment mechanism. The tab is joined to a bottom surface of the base plate. Another implementation is where the attachment mechanism is a screw.

Another disclosed aspect is an outdoor component that includes a housing and a main circuit board. An expansion card bracket is coupled to the main circuit board. The expansion card bracket includes a base plate having a top surface to hold an expansion card. An aperture is formed through the base plate. A heater module is aligned with the aperture to heat an area of the expansion card.

A further implementation of the example outdoor component is where the outdoor component is an edge server. Another implementation is where the expansion card is a PCIe compliant expansion card. Another implementation is where the example outdoor component includes riser board on one end of the base plate and a card support on the other end of the base plate, wherein the riser board includes a first connector mateable with the expansion card and a second connector mateable to a socket on the main circuit board. Another implementation is where the heater module includes a film heater, a heat transmission pad positioned on the film heater, wherein the heat transmission pad allows heat transmission between the film heater and the expansion card. Another implementation is where the heater module includes a tab with an attachment mechanism for attachment to a bottom surface of the base plate. Another implementation is where the attachment mechanism is a screw. Another implementation is where the expansion card bracket includes a side wall perpendicular to the base plate.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1A is a side view of an expansion card installed on a prior art expansion card bracket with a heater and a thermal pad;

FIG. 1B is a top perspective view of the assembled prior art expansion card bracket and the expansion card;

FIG. 1C is a perspective view of the prior art expansion bracket and expansion card showing a problem of misalignment of the thermal pad from installation of the expansion card;

FIG. 2A is an exterior perspective view of a radio communication network component that includes an example expansion card bracket with a heater that allows better thermal transmission, according to certain aspects of the present disclosure;

FIG. 2B is a see-through side view of the component in FIG. 2A according to certain aspects of the present disclosure;

FIG. 3A is an exploded side view of the components of the example expansion card bracket structure for a heater, according to certain aspects of the present disclosure;

FIG. 3B is a side view of the assembled components of the example expansion card bracket structure for a heater, according to certain aspects of the present disclosure;

FIG. 3C is a bottom view of the expansion card bracket structure in FIG. 3A, according to certain aspects of the present disclosure;

FIG. 3D is a perspective exploded view of the components of the expansion card bracket structure in FIG. 3A, according to certain aspects of the present disclosure;

FIG. 4 is a thermal map of a simulation of the example expansion card bracket, according to certain aspects of the present disclosure;

FIG. 5 is a graph of the operational temperature and time for the example expansion card bracket in comparison with a known bracket, according to certain aspects of the present disclosure.

### DETAILED DESCRIPTION

The present disclosure is directed toward a new structural design of an expansion card bracket that includes a separate heater module with a film heater and thermal pad. The heater module allows an expansion card to be installed on the expansion card bracket prior to attaching the heater module. The ability to subsequently attach the heater module, avoids the expansion card impacting the alignment of the thermal pad between an area of the expansion card and the film heater. This ensures that the heat generated by the film heater can be effectively transferred to the card, thereby preventing overheating, and burning out the heater. The example expansion card bracket can also prevent the expansion card from bending under the force from the heat module as the expansion card is fixed in the bracket before the heat module is installed.

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation. ” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

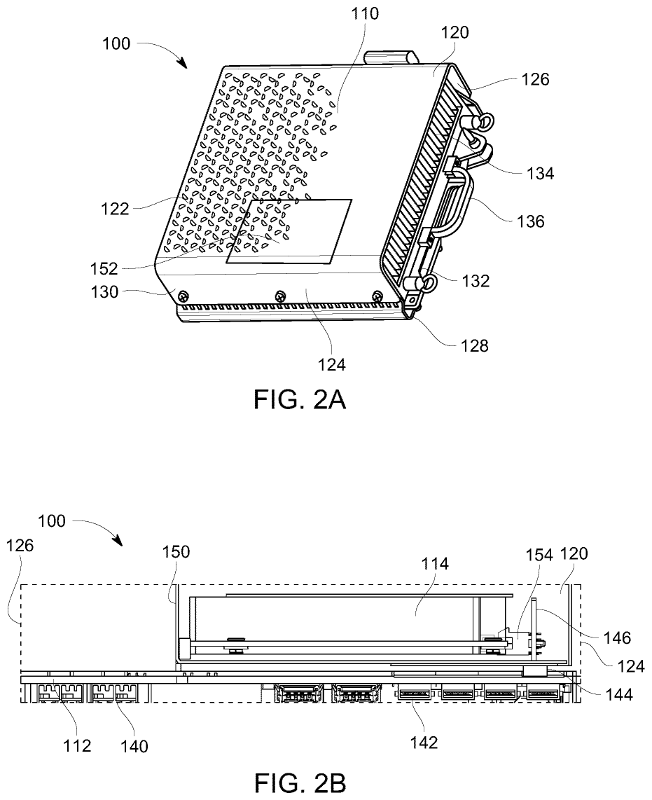

FIG. 2A is an exterior perspective view of a radio communication network component 100. FIG. 2B is a see-through side view of the radio communication network component 100 showing the example expansion card bracket in relation to a main circuit board. In this example, the component 100 is designed for outdoor installation to support a radio communication network. The example component 100 is a 5G edge server component that includes a bracket for an expansion card. However, the principles described herein may be applied to any component with an expansion card designed for outdoor operation such as a distributed unit (DU), radio unit (RU), or an active antenna unit (AAU) or the like.

In this example, the component 100 includes a housing 110, which holds a main printed circuit board 112, which may be a motherboard. The housing 110 is fabricated from a durable metal that can provide protection from environmental conditions. In this example, the component 100 typically includes one or more PCIe expansion cards that may be installed on the main printed circuit board 112 to enhance the functionality of the component 100. The main printed circuit board 112 supports various electronic components performing functions for supporting 5G communications. Thus, the printed circuit board 112 will typically include a CPU and other processors, double data rate (DDR) and non-volatile memory, physical layer key generation circuits, and small form-factor pluggable (SFP) optical and RJ45 type connectors.

The housing 110 includes a top cover component 120 that has a top plate 122 joined with two parallel side plates 124 and 126. The top cover component 120 mates with a base member 128 that includes side flanges that may be bolted to the corresponding side plates 124 and 126 to enclose the main printed circuit board 112. The housing 110 includes a front side 130 and a back side 132. The back side 132 includes a series of vents 134 for cooling the internal components as well as a handle 136 for assistance in lifting the component 100. The front side 130 includes various connectors for cables that receive and transmit signals from external devices to components on the main printed circuit board 112. For example, the component on the main printed circuit board 112 may be coupled to a series of transceiver cages 140 that hold optical transceivers and other connection sockets 142 for wire cables that are on the front side 130.

The main printed circuit board 112 also includes an expansion socket 144 for receiving a connector of a vertical riser board 146. Although only one expansion socket 144 is shown for illustration purposes in FIG. 2B, the main printed circuit board 112 may have multiple expansion sockets for multiple expansion cards that incorporate the principles herein. The vertical riser board 146 supports an expansion card, as will be explained below. An example expansion card bracket 150 is attached to the main printed circuit board 112. The expansion card bracket 150 holds an expansion card 152 that has connectors, such as PCIe compliant edge connectors, which allow connection of the expansion card 152 to a connector socket 154 on the riser board 146. The riser board 146 allows communication of power and data signals with the expansion card 152 via the expansion socket 144 on the main printed circuit board 112. In this example, the expansion card bracket 150 includes a separate heater module that allows operation of the expansion card 152 in cold temperatures.

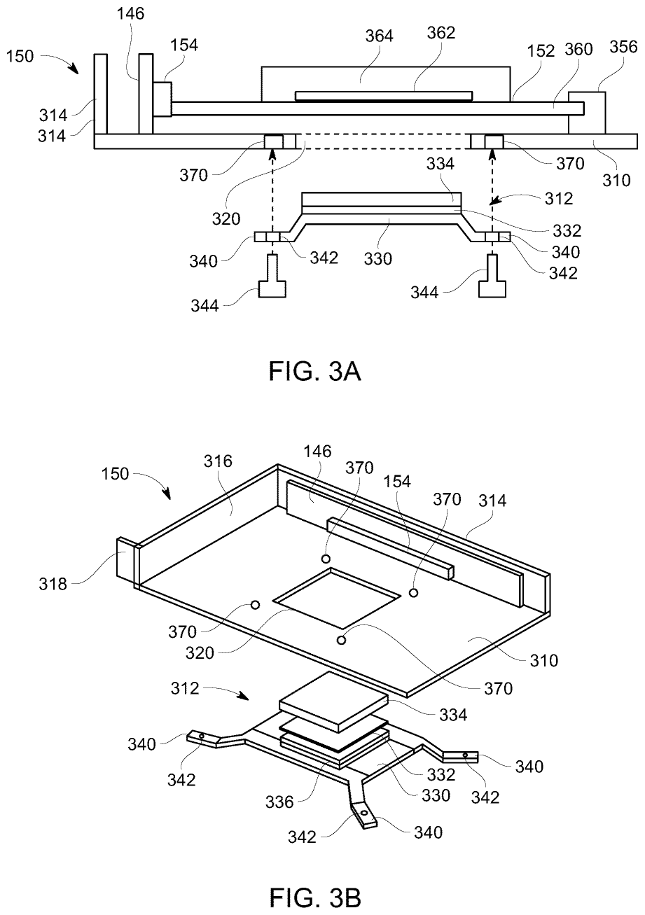

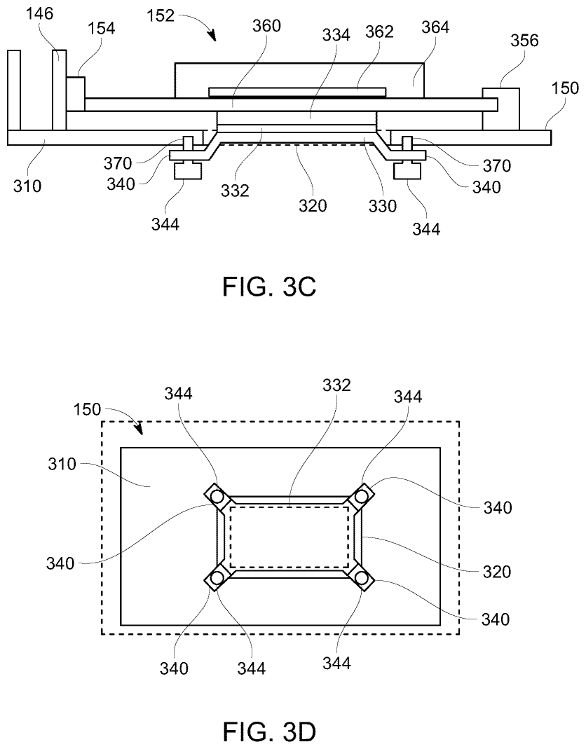

In this example, the expansion card 152 is a smart network interface controller (NIC) card. Other expansion cards may include an acceleration card for networking, a storage device, a processor, or other PCIe compatible devices. Although a single expansion card 152 is shown with the bracket 150 in FIG. 3B, additional expansion cards may be installed with brackets similar to the bracket 150 and additional sockets similar to the expansion socket 144 on the main printed circuit board 112.

The material of the expansion card bracket 150 is a heat conductive material such as aluminum, copper, graphite or a similar material to support the expansion card 152. The expansion card bracket 150 may include registration features that allows the expansion card bracket 150 to be attached to the main printed circuit board 112.

FIG. 3A is a close up exploded side view of components of the example expansion card bracket 150 in FIG. 2A. FIG. 3B is an exploded perspective view of the components of the example expansion card bracket 150 in FIG. 2A. FIG. 3C is a side view of the assembled components of the example expansion card bracket 150. FIG. 3D is a bottom view of the assembled expansion card bracket 150. The expansion bracket 150 includes a base plate 310 and a heat spreader module 312. The base plate 310 is generally rectangular shaped with two side walls 314 and 316 that assist in holding the expansion card 152. A tab 318 extends from the wall 314 to assist in mounting the expansion card bracket 150. An aperture 320 is formed in the center base plate 310. The heat spreader module 312 is suspended under center base plate 310 to cover the aperture 320. As will be explained, the aperture 320 is aligned with the area of the expansion card 152 with a critical operational component, such as a processor, that requires additional heating to operate in extremely cold conditions.

The heat spreader module 312 includes a rectangular heat spreader plate 330. The heat spreader plate 330 supports a thin film heater 332 and a heat transmission or thermal pad 334. The heat spreader plate 330 is generally rectangular and has an area slightly larger than the aperture 320 to allow the heat spreader plate 330 to be inserted under the aperture 320. The top surface of the heat spreader plate 330 has a raised support 336 that holds the thin film heater 332. The thin film heater 332 has heating elements that are powered by wires (not shown) connected to a power source. The heat spreader plate 330 has four corner tabs 340 that each include a screw hole 342. A set of screws 344 may be inserted through each of the corresponding screw holes 342.

As shown in the assembled side view in FIG. 3C, the expansion card 152 includes a circuit board 360. The circuit board 360 has an area where a socket for a processor 362 is located. A heat sink 364 is provided over the processor 362 to transfer heat away from the processor 362. The area where the processor 362 is positioned on the circuit board 360 is aligned with the area of film heater 332 on the heat spreader plate 330. The base plate 310 supports the riser board 146 in a perpendicular position relative to the base plate 310. One end of the circuit board 360 includes an edge connector with golden fingers that may be inserted in the connector socket 154 of the riser 146. An opposite edge of the circuit board 360 of the expansion card 152 may be inserted in a slot of a card support 356 that is attached to the base plate 310. The expansion card 152 is thus attached to the expansion card bracket 150 via the connector socket 154 of the riser board 146 and the card support 356.

After the expansion card 152 is attached to the expansion card bracket 150, the heat spreader module 312 may then be attached to the underside of the base plate 310 to cover the aperture 320. The aperture 320 allows the thermal pad 334 to directly contact the area of the circuit board 360 corresponding to the processor 362 of the now fixed expansion card 152. The screw holes 342 of each of the tabs 340 are aligned with corresponding screw holes 370 in the base plate 310.

The heat spreader plate 330 may be attached to the edges of the bottom of the base plate 310 via screws 344 that attach the tabs 340 through the screw holes 342 to corresponding holes 370 in the base plate 310. The assembly of the film heater 332 after the expansion card 152 has been fixed on the expansion card bracket 150 prevents shifting of the thermal pad 334 during the process of attaching the expansion card 152 to the expansion card bracket 150. The attachment of the heat spreader plate 330 to the base plate 310 also creates force on the thermal pad 334 to create better thermal contact between the film heater 332, the thermal pad 334, and the underside area of the circuit board 360. This provides more efficient heat distribution from the film heater 332 through the thermal pad 334 to the circuit board 360.

In this example, the film heater 332, in conjunction with the expansion card bracket 150, allows operation of the expansion card 152 in temperatures as low as −40° C. In this example, the film heater 332 has a power output of 26 W and has the dimensions of 35 mm×35 mm×0.3 mm. Of course, other power ranges and sizes may be used for the film heater 332. Thus, the area of the film heater 332 (35 mm×35 mm) is approximately the area of the processor 362 on the circuit board 360.

The structural design of the example expansion card bracket 150 allows installation of the film heater 332 and the thermal pad 334 in relation to the expansion card 152 without impacting the position of the thermal pad 334. Thus the thermal pad 334 remains in alignment with the film heater 332 when the heat spreader module 312 is attached to the base plate 310. This ensures that the heat generated by the film heater 332 can be effectively transferred to the expansion card 152. The efficient transfer prevents overheating and burn out of the film heater 332. In addition, the example expansion card bracket 150 prevents the expansion card 152 from bending under the force from the heat spreader module 312 as the expansion card 152 is installed in the example expansion card bracket 150 and thus the edge connector is firmly inserted in the connector socket 154 and card support 356 before installation of the heat spreader module 312. The prior installation of the expansion card 152 allows the expansion card 152 to better resist the compressive force applied from attaching the heat spreader module 312.

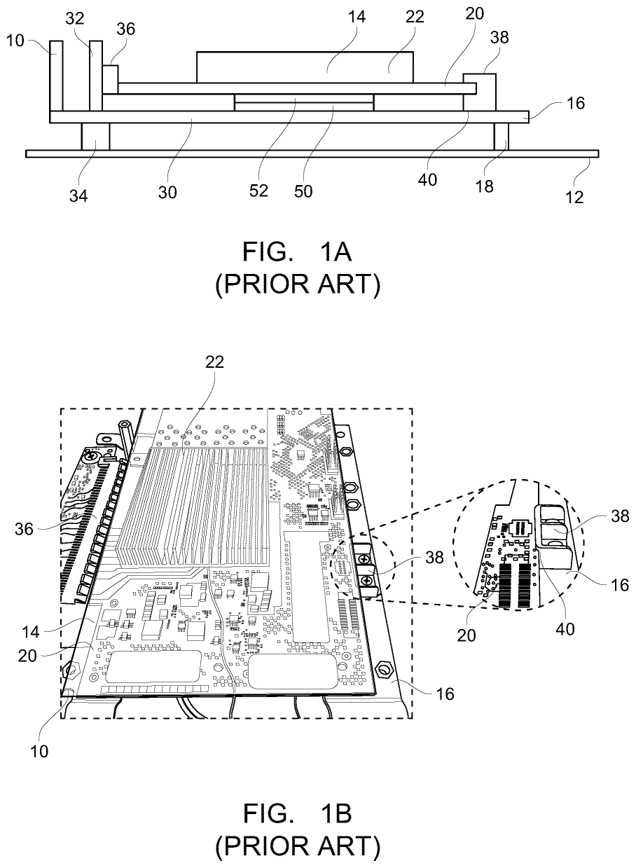

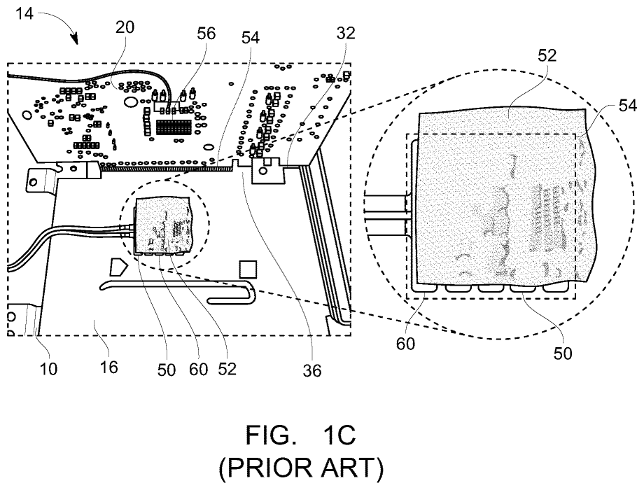

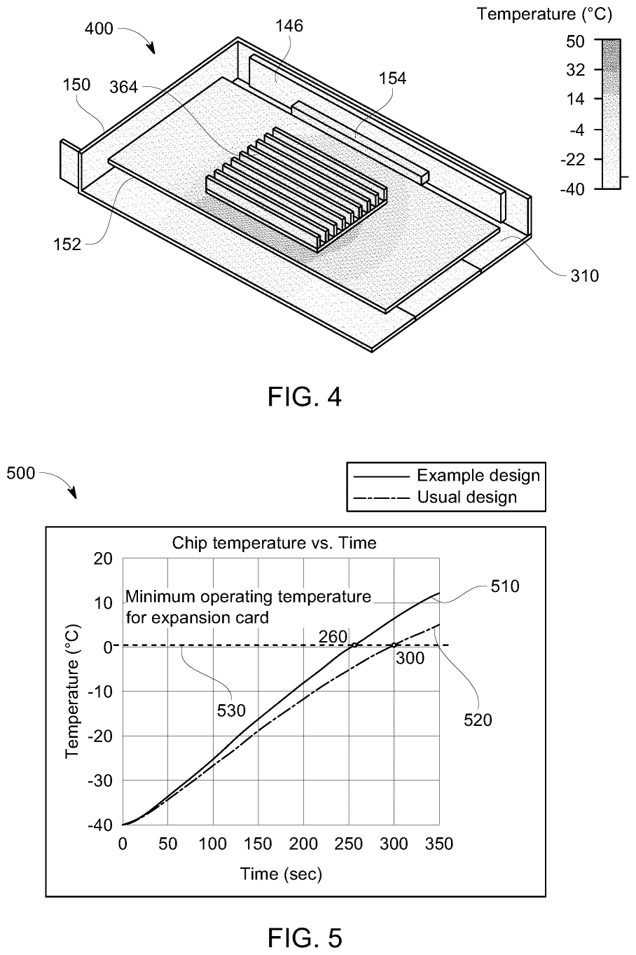

To study the heater efficiency from the design of the example expansion card bracket 150, a thermal simulation was conducted to compare a known expansion bracket design such as that shown in FIG. 1A, with the example expansion card bracket 150 in FIG. 3A. FIG. 4 is a heat simulation 400 of the example expansion card bracket 150 and the expansion card 152. The heat simulation 400 shows distribution of heat from the heater spreader module 312 in FIG. 3C in the base plate 310, the circuit board 360 of the expansion card 152, the heat sink 364, the riser board 146, and the connector socket 154. The thermal simulation was tested to show distribution of heat over time on the expansion card bracket 150 and the expansion card 152 in FIG. 4. The test results of the thermal simulation in FIG. 4 shows the superior heat efficiency of the example expansion card bracket 150 in FIGS. 3A-3D.

The simulation was conducted with the boundary conditions of an operating temperature at −40° C., a heater power of 26 W, and operating the expansion card in still air. The simulation was based on observing how much heating time was required for the expansion card 152 to be heated from −40° C. to 0° C. by the film heater of the expansion card bracket 150.

The testing showed that a lower percentage of the heat (47.7%) from the film heater was transferred to the expansion card in the known design. Further, the known design required a relatively long heating time to reach 0° C. (˜300 s). In contrast, the example expansion card bracket 150 with the heat spreader module 312 can transfer more heat (60.4%) from the film heater to the expansion card. Heating time was also shorter for achieving the necessary heat transfer to the expansion card, taking only 260 seconds for heating the expansion card to 0° C., which is a 13% improvement in heating time as compared to that of the known bracket. Thus, in comparison to the known expansion card bracket, the example expansion card bracket 150 conducts more heat to the expansion card (higher heater efficiency, 47.7% compared with 60.4%) and reduces heating time (300s compared with 260s) to save energy.

FIG. 5 is a graph 500 that plots the time that an expansion card may be heated using the known design (as a plot 520) versus the example expansion card (as plot 510). The graph 500 shows the example expansion card bracket 150 reduces the time to reach the minimum operating temperature (shown as a line 530) of the expansion card (0° C.) by about 13% compared to the usual design.

The example expansion card bracket 150 prevents lateral force on the thermal pad 334 during installation of the expansion card 152, thereby avoiding thermal pad displacement and damage to the thermal pad. Compared with the known card bracket design, the example expansion card bracket 150 separates the heat spreader module 312 from the expansion card bracket 150. This design helps to avoid heat conduction to the base plate 310 of the expansion card bracket 150 and increase heat conducted to the expansion card 152. The heat spreader module 312 is easy to attach to and detach from the base plate 310, thereby making service of the expansion card 152 convenient. The heat spreader module 312 allows heat emitted from the film heater 332 to be more concentrated thus improving heating efficiency.

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. An expansion card bracket comprising:
a base plate having a top surface to hold an expansion card;
an aperture is formed through the base plate; and
a heater module attached to the base plate, the heater module being aligned with the aperture to heat an area of the expansion card.

2. The expansion card bracket of claim 1, wherein the expansion card is compliant with PCIe standards.

3. The expansion card bracket of claim 1, further comprising a riser board on one end of the base plate and a card support on the other end of the base plate, wherein the riser board includes a first connector mateable with the expansion card and a second connector mateable to a socket on a main circuit board.

4. The expansion card bracket of claim 1, wherein the heater module includes a film heater.

5. The expansion card bracket of claim 4, wherein the heater module includes a heat transmission pad positioned on the film heater, wherein the heat transmission pad allows heat transmission between the film heater and the expansion card.

6. The expansion card bracket of claim 1, wherein the heater module includes a tab with an attachment mechanism for attachment to a bottom surface of the base plate.

7. The expansion card bracket of claim 6, wherein the attachment mechanism is a screw.

8. The expansion card bracket of claim 1, further comprising a side wall perpendicular to the base plate.

9. A heater module for mating to an expansion card bracket, the heater module comprising:
a spreader plate having an attachment mechanism for attachment to a base plate of the expansion card bracket, the base plate having an aperture;
a film heater positioned on the spreader plate to be aligned with the aperture of the base plate of the expansion card bracket; and
a heat transmission pad positioned on the film heater.

10. The heater module of claim 9, wherein the expansion card bracket holds an expansion card compliant with PCIe standards.

11. The heater module of claim 9, wherein the spreader plate includes a tab with the attachment mechanism, wherein the tab is joined to a bottom surface of the base plate.

12. The heater module of claim 11, wherein the attachment mechanism is a screw.

13. An outdoor component comprising:
a housing;
a main circuit board;
an expansion card bracket coupled to the main circuit board, the expansion card bracket including:
a base plate having a top surface to hold an expansion card;
an aperture formed through the base plate; and
a heater module aligned with the aperture to heat an area of the expansion card.

14. The outdoor component of claim 13, wherein the outdoor component is an edge server.

15. The outdoor component of claim 13, wherein the expansion card is a PCIe compliant expansion card.

16. The outdoor component of claim 13, further comprising a riser board on one end of the base plate and a card support on the other end of the base plate, wherein the riser board includes a first connector mateable with the expansion card and a second connector mateable to a socket on the main circuit board.

17. The outdoor component of claim 13, wherein the heater module includes a film heater, a heat transmission pad positioned on the film heater, wherein the heat transmission pad allows heat transmission between the film heater and the expansion card.

18. The outdoor component of claim 13, wherein the heater module includes a tab with an attachment mechanism for attachment to a bottom surface of the base plate.

19. The outdoor component of claim 18, wherein the attachment mechanism is a screw.

20. The outdoor component of claim 13, wherein the expansion card bracket includes a side wall perpendicular to the base plate.
